(19) United States
(12) Patent Application Publication
(10) Pub. No.: US 2015/0306868 A1
(43) Pub. Date: Oct. 29, 2015

(54) IMAGE FORMING APPARATUS, IMAGE FORMING METHOD, AND RECORDING

(71) Applicant: Kenichi Ohhashi, Kanagawa (JP)

(72) Inventor: Kenichi Ohhashi, Kanagawa (JP)

(73) Assignee: RICOH COMPANY, LTD., Tokyo (JP)

(21) Appl. No.: 14/694,362

(22) Filed: Apr. 23, 2015

(30) Foreign Application Priority Data
Apr. 28, 2014 (JP) 2014-092479

(51) Int. Cl. B41J 2/01; G01R 31/36

(52) U.S. Cl. CPC B41J 2/01; G01R 31/3606

(57) ABSTRACT

An image forming apparatus driven with stored power from a battery includes an image forming unit to perform printing; a battery remaining amount detecting unit to detect a remaining amount of the stored power of the battery; and an enforced printing unit to determine whether the detected remaining amount of the stored power of the battery reaches a threshold value indicating to stop printing, and controls the image forming unit to continuously perform printing even when it is determined that the detected remaining amount reaches the threshold value.

### CROSS-REFERENCE TO RELATED APPLICATION

This patent application is based on and claims priority pursuant to 35 U.S.C. §119 from Japanese Patent Application No. 2014-092479, filed on Apr. 28, 2014 in the Japan Patent Office, which is hereby incorporated by reference herein in its entirety.

### BACKGROUND

1. Technical Field

Exemplary embodiments of the present disclosure generally relate to an image forming apparatus driven with a battery, an image forming method, and a non-transitory recording medium.

2. Description of the Related Art

Among image forming apparatuses such as a printer that prints data received via internet or from host devices such as a personal computer, a personal digital assistant (hereinafter referred to as PDA), or a mobile phone, there are those that include a battery as a power source and are driven with power of the battery.

In such image forming apparatuses, when power of the battery is depleted during an image forming operation, the image forming operation stops in the middle of the action.

To cope with the above-described issue, technologies such as determining whether or not to conduct an image forming operation according to a remaining amount of power detected in the battery before starting the image forming operation (i.e., printing) are known.

For example, there is a disclosure of a method of detecting a remaining amount of power of a battery, and determining not to print when the remaining amount of power of the battery is insufficient with respect to an amount of power consumption to complete all processes of a print job.

However, in the above-described conventional technology, there is an issue of not being able to print when the remaining amount of power of the battery, in an image forming apparatus, is insufficient with respect to the amount of power consumption to complete the entire print job.

### SUMMARY

In view of the foregoing, in an aspect of this disclosure, there is provided a novel image forming apparatus driven with stored power from a battery including an image forming unit to perform printing; a battery remaining amount detecting unit to detect a remaining amount of the stored power of the battery; and an enforced printing unit to determine whether the detected remaining amount of the stored power of the battery reaches a threshold value indicating to stop printing, and controls the image forming unit to continuously perform printing even when it is determined that the detected remaining amount reaches the threshold value.

These and other aspects, features, and advantages will be more fully apparent from the following detailed description of illustrative embodiments, the accompanying drawings, and associated claims.

### BRIEF DESCRIPTION OF THE DRAWINGS

The aforementioned and other aspects, features, and advantages of the present disclosure will be better understood by reference to the following detailed description when considered in connection with the accompanying drawings, wherein:

FIG. 1 is a cross-sectional view of an internal configuration of an inkjet printer that is an example of the image forming apparatus according to an embodiment of the present invention;

FIG. 2 is a plan view of main parts of the internal configuration of the inkjet printer;

FIG. 3 is a block diagram of an example of a configuration of a control unit and its peripheral of the inkjet printer;

FIG. 4 is a perspective view of an example of an exterior of the inkjet printer;

FIG. 5 is a perspective view of a battery included in the inkjet printer of FIG. 4;

FIG. 6 is an enlarged view of a battery status display panel of the inkjet printer of FIG. 4;

FIG. 7 is an example text display of a liquid crystal display of an operation panel of the inkjet printer of FIG. 4;

FIG. 8 is a block diagram of an example of a configuration of a power source unit and related units of the inkjet printer;

FIG. 9 is an example of a print setting screen of a printer driver of a host device that enables a setting of enforced printing;

FIG. 10 is a flow chart illustrating example operation of print control performed by a CPU of the control unit of FIG. 3;

FIG. 11 is another example of the print setting screen of the printer driver of the host device that enables the setting of enforced printing in a second exemplary embodiment;

FIG. 12 is a flow chart illustrating example operation of print control performed by a CPU of a control unit of FIG. 11; and

FIG. 13 is a flow chart illustrating example operation of print control performed by a CPU of a control unit of a third exemplary embodiment including a setting of layout printing.

The accompanying drawings are intended to depict exemplary embodiments of the present disclosure and should not be interpreted to limit the scope thereof. The accompanying drawings are not to be considered as drawn to scale unless explicitly noted.

### DETAILED DESCRIPTION

Hereinafter, exemplary embodiments of the present invention are described in detail with reference to the drawings. However, the present invention is not limited to the exemplary embodiments described below, but may be modified and improved within the scope of the present disclosure.

In describing embodiments illustrated in the drawings, specific terminology is employed for the sake of clarity. However, the disclosure of this patent specification is not intended to be limited to the specific terminology so selected and it is to be understood that each specific element includes all technical equivalents that have the same function, operate in a similar manner, and achieve similar results.

In a later-described comparative example, illustrative embodiment, and alternative example, for the sake of simplicity, the same reference numerals will be given to constituent elements such as parts and elements having the same functions, and redundant descriptions thereof omitted.

There is provided a novel image forming apparatus that enables an image forming action even when a remaining amount of power of a battery, driving the image forming apparatus, reaches a threshold value or less that is a point at which the image forming action is stopped.

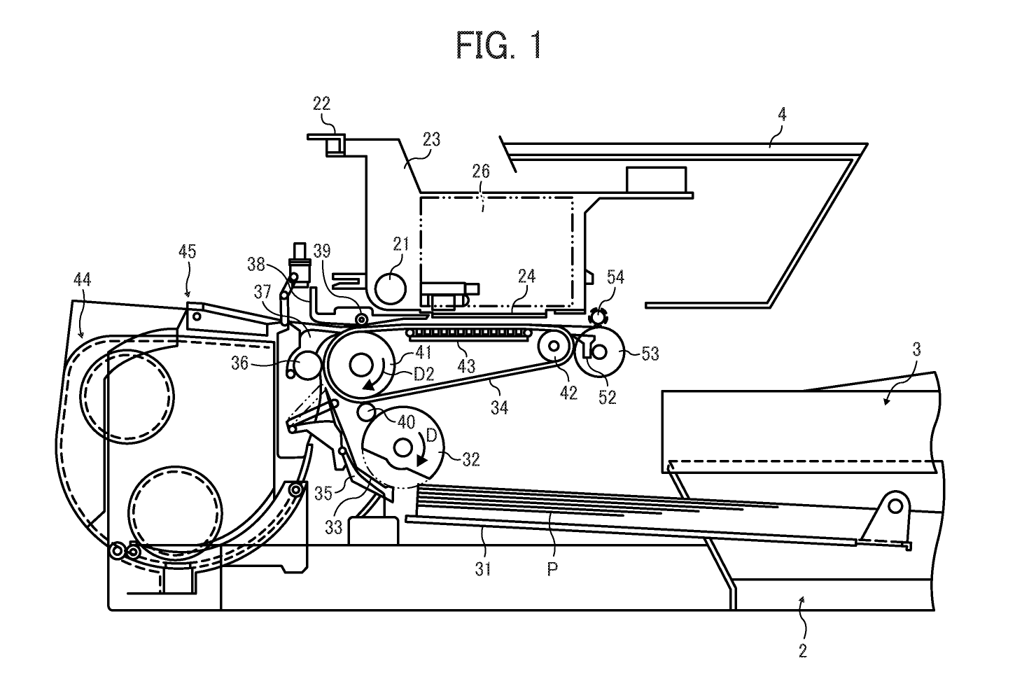

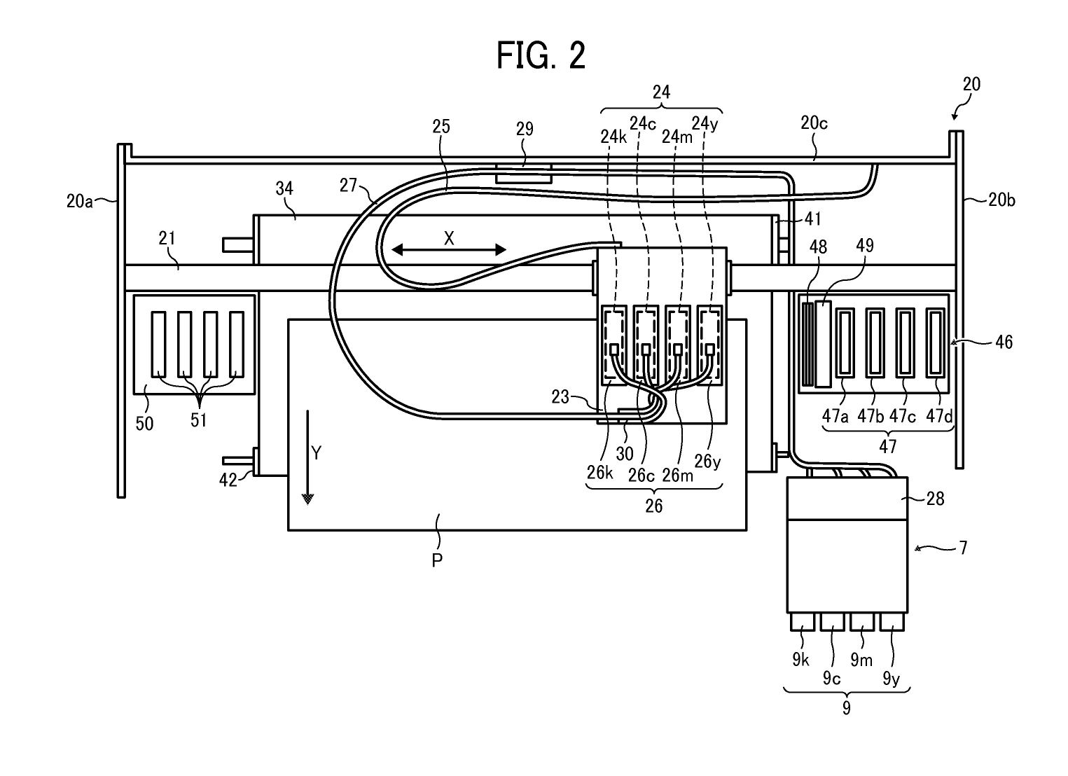

The following is a description of an internal configuration of an inkjet printer that is an example of an image forming apparatus according to an embodiment of the present invention with reference to FIG. 1 and FIG. 2.

FIG. 1 is a cross-sectional view of the internal configuration of the inkjet printer. FIG. 2 is a plan view of main parts of the internal configuration of the inkjet printer.

A mechanical member (i.e., image forming unit) of the inkjet printer, within a main body of the inkjet printer including an upper cover 4, includes a carriage 23 supported by a stay 22 as shown in FIG. 1, and a guide rod 21 that is a guide member laterally bridging a side plate 20a and a side plate 20b configuring sides of a frame 20 as shown in FIG. 2. The carriage 23 scans in a main scanning direction shown by arrow X in FIG. 2 due to a timing belt unit and a main scanning motor 61 described later.

The carriage 23 includes a recording head 24 configured of four inkjet heads that discharge ink droplets of colors of black (K), cyan (C), magenta (M), and yellow (Y), respectively. Each of the four inkjet heads of the recording head 24 includes multiple nozzles, and the multiple nozzle arrays are arranged in a direction (i.e., sub-scanning direction) perpendicular to the main scanning direction. Discharge direction of ink droplets of each color is a downward direction of FIG. 1.

As shown in FIG. 2, the four inkjet heads of the recording head 24 that discharge ink droplets of colors of black (K), cyan (C), magenta (M), and yellow (Y) are designated as a first inkjet head 24k, a second inkjet head 24c, a third inkjet head 24m, and a fourth inkjet head 24y. The generic term “recording head 24” is used hereinafter when no distinction is made with respect to colors.

An inkjet head including an energy generating unit to discharge ink may be employed for the four inkjet heads that configure the recording head 24. Specific examples of the energy generating unit include, but are not limited to, a piezoelectric actuator such as a piezoelectric element, a thermal actuator, a shape memory alloy actuator, and an electrostatic actuator.

The thermal actuator employs phase change due to film boiling of a liquid using an electro-thermal conversion element such as a heating resistor. The shape memory alloy actuator employs metal phase change due to temperature change.

It is to be noted that the configuration of the recording head 24 is not limited to the above-described example. The recording head 24 may be configured of one inkjet head or multiple inkjet heads having one nozzle array or multiple nozzle arrays that discharge ink droplets of one color or multiple colors.

The recording head 24 includes a driver IC and is connected to a control unit described later with a harness 25 (i.e., flexible print cable) shown in FIG. 2. Accordingly, data transaction is possible between the recording head 24 and the control unit.

The carriage 23 further includes a sub-tank 26 that holds ink for each color to supply ink of each color to the recording head 24.

As shown in FIG. 2, the sub-tank 26 for each color are designated as a first sub-tank 26k for black (K), a second sub-tank 26c for cyan (C), a third sub-tank 26m for magenta (M), and a fourth sub-tank 26y for yellow (Y). The generic term “sub-tank 26” is used hereinafter when no distinction is made with respect to colors.

The first sub-tank 26k, the second sub-tank 26c, the third sub-tank 26m, and the fourth sub-tank 26y are connected to a first ink cartridge 9k, a second ink cartridge 9c, a third ink cartridge 9m, and a fourth ink cartridge 9y with an ink supply tube 27, respectively. Each color ink in each sub-tank 26 is replenished from the first ink cartridge 9k, the second ink cartridge 9c, the third ink cartridge 9m, and the fourth ink cartridge 9y, respectively. The generic term “ink cartridge 9” is used hereinafter when no distinction is made with respect to colors.

A supplying pump unit 28 to convey ink to each of the ink cartridges 9 is provided in a cartridge loading unit 7. The ink supply tube 27 is held by a holder 29 at a rear plate 20c of the frame 20 along the way to the sub-tank 26. Further, the ink supply tube 27 is attached by a fixing rib 30 to the carriage 23.

As shown in FIG. 1, a sheet feeding unit to feed sheets P stacked on a sheet stacking unit 31 (i.e., elevating/lowering plate) of a sheet feed tray 2 includes a separating pad 33 and a sheet feeding roller 32 (e.g., semi-circular roller) to feed the sheets P, sheet-by-sheet, from the sheet stacking unit 31 by rotating in a direction of a first arrow D. The separating pad 33 is formed of a member having a large friction coefficient, and is pressed against the sheet feeding roller 32.

The inkjet printer further includes a conveyance unit to convey the sheets P, separated sheet-by-sheet and fed by the sheet feeding unit, below the recording head 24. The conveyance unit includes a conveyance belt 34 to convey the sheet P with electrostatic attraction; a guide 35; and a counter roller 36 that sandwiches the sheet P, conveyed via the guide 35 from the sheet feeding unit, with the conveyance belt 34. The conveyance unit further includes a conveyance guide 37 to make the sheet P, conveyed in an approximately vertical direction and then turned in an approximate 90° turn, follow along the conveyance belt 34; a pressing member 38; a leading edge pressing roller 39 pressed against the conveyance belt 34 with the pressing member 38; and a charging roller 40 serving as a charging unit to charge a surface of the conveyance belt 34.

The conveyance belt 34, having an endless belt shape, is stretched over a conveyance roller 41 and a tension roller 42. The conveyance belt 34 rotates in the sub-scanning direction, shown by an arrow Y in FIG. 2, when the conveyance roller 41 is rotated in a direction of a second arrow D2 by a sub-scanning motor 62 described later.

The conveyance belt 34 includes an outer layer serving as a sheet attraction surface formed of, for example, a pure resin material having a thickness of approximately 40 μm with no implementation of resistance control, and an inner layer of the same material as the outer layer with an implementation of resistance control using carbon. A specific example of the pure resin material is a pure ethylene tetrafluoroethylene (hereinafter referred to as ETFE) material. The inner layer may be a mid-resistance layer or a grounding layer.

The charging roller 40 serving as a charging unit to charge the surface of the conveyance belt 34 contacts the outer layer of the conveyance belt 34 and is rotated along with the rotation of the conveyance belt 34. Further, a predetermined pressing force is applied to both ends of a shaft of the charging roller 40 to apply a pressure with respect to the conveyance belt 34.

The conveyance roller 41 also serves as a grounding roller (earth roller), and grounds the conveyance layer 34 by contacting the inner layer (i.e., mid-resistance layer) of the conveyance layer 34.

In addition, a second guide member 43 is provided at an inner side of the conveyance layer 34 and is arranged so as to face a printing area of the recording head 24.

An upper surface of the second guide member 43 facing the conveyance belt 34 protrudes toward the recording head 24 side with respect to an external common tangent line of the conveyance roller 41 and the tension roller 42 supporting the conveyance belt 34.

Accordingly, the conveyance belt 34 is pressed up and guided by the upper surface of the second guide member 43 at the printing area, and a highly precise flatness of the conveyance belt 34 is maintained.

The inkjet printer also includes a sheet ejection unit to eject the sheet P after being printed with the recording head 24. The sheet ejection unit includes a separation claw 52 to separate the sheet P from the conveyance belt 34, a first sheet ejection roller 53, a second sheet ejection roller 54, and a sheet ejection tray 3 provided at a lower side of the first sheet ejection roller 53.

A vertical distance from a position between the first sheet ejection roller 53 and the second sheet ejection roller 54 to the sheet ejection tray 3 is made, to a certain extent, large in order to increase a stock amount of the sheet P at the sheet ejection tray 3.

At a rear portion of the main body of the inkjet printer, a double-side sheet feeding unit 44 is detachably attached.

When conducting double-side printing, the double-side sheet feeding unit 44 includes a function to take in and invert the sheet P that is returned with a reverse rotation of the conveyance belt 34, and re-feed the sheet P between the leading edge pressing roller 39 and the conveyance belt 34.

At an upper surface of the double-side sheet feeding unit 44, a manual sheet feed unit 45 is provided to allow a user to manually feed the sheet P.

As shown in FIG. 2, at a non-printing area at one side (i.e., right side of FIG. 2) of the main scanning direction of the carriage 23, a maintaining/recovery unit 46 is provided for maintaining a state of and recovery of the multiple nozzles of the recording head 24.

The maintaining/recovery unit 46 includes a first capping member 47a, a second capping member 47b, a third capping member 47c, and a fourth capping member 47d to cap nozzle surfaces of the first inkjet head 24k, the second inkjet head 24c, the third inkjet head 24m, and the fourth inkjet head 24y, respectively. A generic term “cap 47” is used hereinafter when no distinction is made with respect to which capping member. The maintaining/recovery unit 46 further includes a wiper blade 48 serving as a blade member to wipe the nozzle surfaces, and a blank discharge receiver 49 to receive ink droplets when conducting blank discharge to discharge thickened ink, more specifically, ink droplets that do not contribute to a print.

The first capping member 47a is a suction and moisturizing cap, and the other capping members 47b to 47d are moisturizing caps.

At a non-printing area at the other side (i.e., left side of FIG. 2) of the main scanning direction of the carriage 23, a second blank discharge receiver 50 is provided to receive ink droplets when conducting blank discharge to discharge thickened ink during printing, more specifically, to discharge ink droplets that do not contribute to the print. The second blank discharge receiver 50 includes openings 51 that open along the direction of the multiple nozzle arrays of the recording head 24.

In the inkjet printer with the above-described configuration, the sheets P are separated sheet-by-sheet and fed from the sheet feed tray 2 as shown in FIG. 1, guided in the approximately vertical direction by the guide 35, and conveyed by being sandwiched with the conveyance belt 34 and the counter roller 36. A leading edge of the sheet P is guided to the conveyance guide 37, pressed to the conveyance belt 34 with the leading edge pressing roller 39, and conveyance of the sheet P is turned approximately 90°.

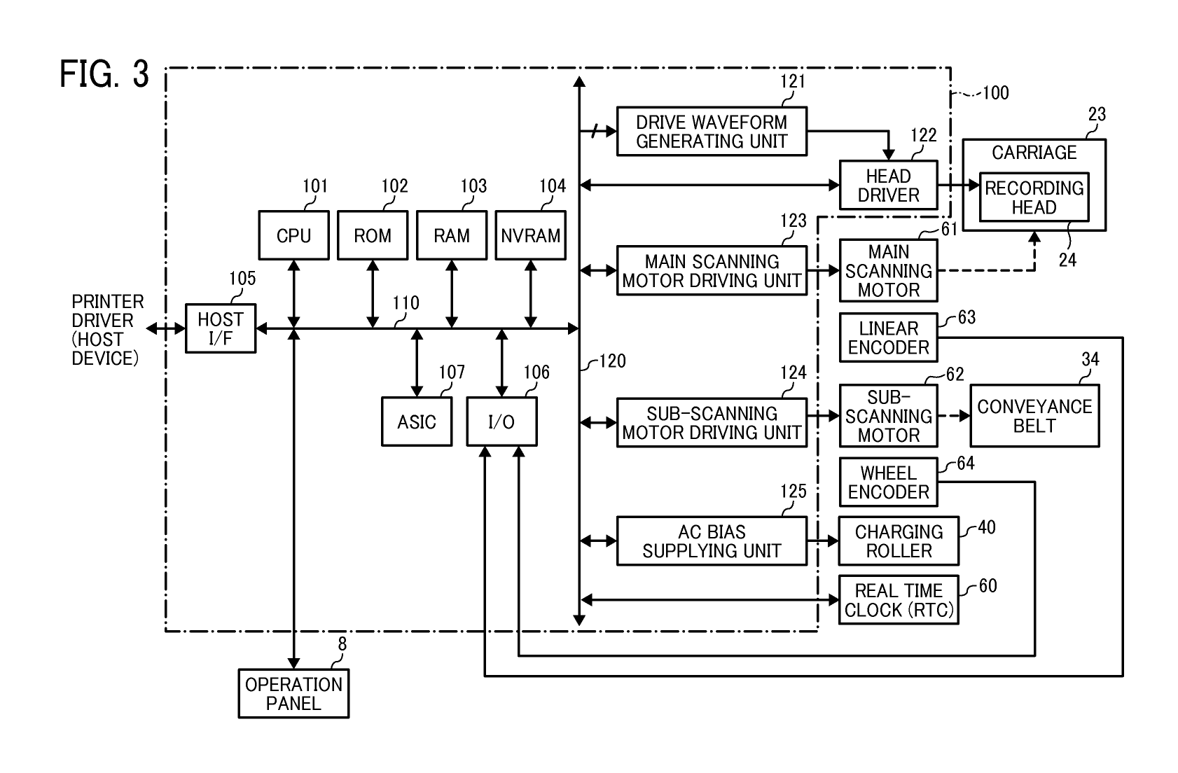

An alternating voltage that repeats a positive output and a negative output from an alternating current (hereinafter referred to as AC) bias supplying unit 125 is applied to the charging roller 40 with a control unit 100 shown in FIG. 3, described in detail later, and the conveyance belt 34 is charged in an alternating charge-voltage pattern (hereinafter may be referred to as alternating charge pattern). More specifically, the conveyance belt 34 is charged in the pattern of band shapes, with a predetermined width, alternating between a positive charge and a negative charge along the sub-scanning direction that is the direction of rotation of the conveyance belt 34.

When the sheet P is conveyed onto the conveyance belt 34 that is charged in the pattern of band shapes alternating between the positive charge and the negative charge, the sheet P also obtains an alternating positive charge and negative charge caused by electrostatic induction in which polarity of the alternating charge of the sheet P is opposite to polarity of the alternating charge of the conveyance belt 34. Accordingly, the sheet P adheres to the conveyance belt 34 by electrostatic attraction with relatively no positional deviation, and the sheet P is accurately conveyed in the sub-scanning direction by rotation of the conveyance belt 34.

By moving the carriage 23 in the main scanning direction and driving the recording head 24 according to an image signal, lines of an image are printed according to a number of nozzles discharging ink droplets on the sheet P at a standstill. Then, the sheet P is conveyed a predetermined amount and lines of the image that come next are printed.

When a printing end signal or a signal indicating that a rear end of the sheet P has reached an end of the printing area in the sub-scanning direction is received, printing is ended and the sheet P is ejected to the sheet ejection tray 3.

At a standby of printing, the carriage 23 is moved to the maintaining/recovery unit 46 and the recording head 24 is capped with the cap 47. Accordingly, discharge failure of ink due to drying of ink is prevented by maintaining a moistened state of the multiple nozzles.

Further, a recovery action in which ink from the multiple nozzles is sucked in by a suction pump (hereinafter may be referred to as “nozzle suction” or “head suction”) to expel thickened ink or bubbles is conducted when the recording head 24 is capped with the cap 47.

Blank discharge to discharge ink that does not contribute to the print is conducted before starting printing and during printing. Thus, as described above, a stable discharging performance of the recording head 24 is maintained.

The following is a description of a configuration of the control unit 100 of the inkjet printer with reference to FIG. 3.

The control unit 100 controls the above-described inkjet printer and is implemented by a micro-computer including a central processing unit 101 (hereinafter referred to as CPU), a read only memory 102 (hereinafter referred to as ROM) serving as a memory to store programs and data related to the programs, a random access memory 103 (hereinafter referred to as RAM) that serves as a data memory storing an image data, a nonvolatile RAM 104 (hereinafter referred to as NVRAM) serving as a nonvolatile memory, a host interface 105 (hereinafter referred to as host I/F), and an input/output member 106 (hereinafter referred to as I/O). The micro-computer including the CPU 101, performs processing or makes determinations described later.

The control unit 100 further includes an application specific integrated circuit 107 (hereinafter referred to as ASIC) to process various signals with respect to the image data, to apply image processing such as rearrangement, and to process other input/output signals that control the inkjet printer. The host I/F 105 transmits or receives data signals with a host device 15 such as a personal computer that transmits print data (i.e., image forming job data).

The above-described elements of the micro-computer are connected by a CPU bus 110 so that data and signals can be reciprocally exchanged with each other. An operation panel 8 is also connected to the CPU bus 110.

A drive waveform generating unit 121 and a head driver 122 are connected to a control bus 120 that is connected to the CPU bus 110. The control bus 120 is also connected to a main scanning motor driving unit 123, a sub-scanning motor driving unit 124, the AC bias supplying unit 125, and a real time clock 60 (hereinafter referred to as RTC) to acquire current time. The above-described elements of the micro-computer are all controlled by the CPU 101. The RTC 60 corresponds to a digital electronic clock that outputs information of year, month, day, and current time.

The AC bias supplying unit 125 converts a direct current (hereinafter referred to as DC) voltage from a DC power source to a high AC voltage and applies an AC bias to the charging roller 40.

It is to be noted that in FIG. 3, a portion that controls operation of the maintaining/recovery unit 46 shown in FIG. 2 is omitted.

A linear encoder 63 outputs a detection signal according to moving speed and an amount of movement of the carriage 23 moved by the main scanning motor 61. A wheel encoder 64 outputs a detection signal according to moving speed and an amount of movement of the conveyance belt 34 rotated by the sub-scanning motor 62.

The control unit 100 receives, via the host I/F 105, the print data from a printer driver of the host device 15 transmitted over a communication cable or network. It is to be noted that the host device 15 is a device that causes the inkjet printer to print (i.e., form the image). Specific examples of the host device 15 include, but are not limited to, an information processing device such as a personal computer, an image reading device such as an image scanner, and an imaging device such as a digital camera.

When the print data is received by the host I/F 105, the CPU 101 reads out the print data in a receiving buffer of the host I/F 105 and analyzes the print data. The ASIC 107 conducts image processing, conducts rearrangement of the image data, synchronizes the processed image data (i.e., dot pattern data) and a clock signal, and outputs the processed and synchronized image data as serial data to the head driver 122.

It is to be noted that with respect to generating the dot pattern data for outputting the image, by storing font data in the ROM 102, the control unit 100 of the inkjet printer may generate the dot pattern data. However, the image data may be prepared as bitmap data at the printer driver of the host device 15 and then transferred to the control unit 100 of the inkjet printer. In this exemplary embodiment, the printer driver prepares the image data as the bitmap data.

The drive waveform generating unit 121 is configured of an amplifier and a digital-to-analog (hereinafter referred to as DA) converter that conducts digital-to-analog conversion of pattern data of a driving pulse, stored in the ROM 102, read out by the CPU 101. The drive waveform generating unit 121 outputs a driving waveform configured of a single driving pulse or multiple driving pulses to the head driver 122.

The head driver 122 includes, for example, a shift register to input the clock signal and the serial data that is the image data, a latch circuit to latch a register value, and a level conversion circuit (i.e., level shifter) to change a level of an output value from the latch circuit, and an analog switch array (i.e., switching unit) in which ON/OFF is controlled by the level shifter.

By controlling ON/OFF of the analog switch array, the driving pulse included in the driving waveform provided from the drive waveform generating unit 121 is selectively applied to a pressure generating unit of the recording head 24. Accordingly, the recording head 24 is driven and ink droplets are discharged.

The main scanning motor driving unit 123 drives the main scanning motor 61 and makes the carriage 23 reciprocate in the main scanning direction.

The sub-scanning motor driving unit 124 drives the sub-scanning motor 62 and rotates the conveyance roller 41 shown in FIG. 1 and FIG. 2. As described above, the conveyance belt 34 is rotated in a manner in which the sheet P is intermittently conveyed in the sub-scanning direction.

The AC bias supplying unit 125 controls the alternating charge pattern of the conveyance belt 34 by conducting ON/OFF control of the AC bias supplied to the charging roller 40, and makes electrostatic attraction of the sheet P to the conveyance belt 34 possible by charging the conveyance belt 34.

The following is a description an example of an exterior of the inkjet printer.

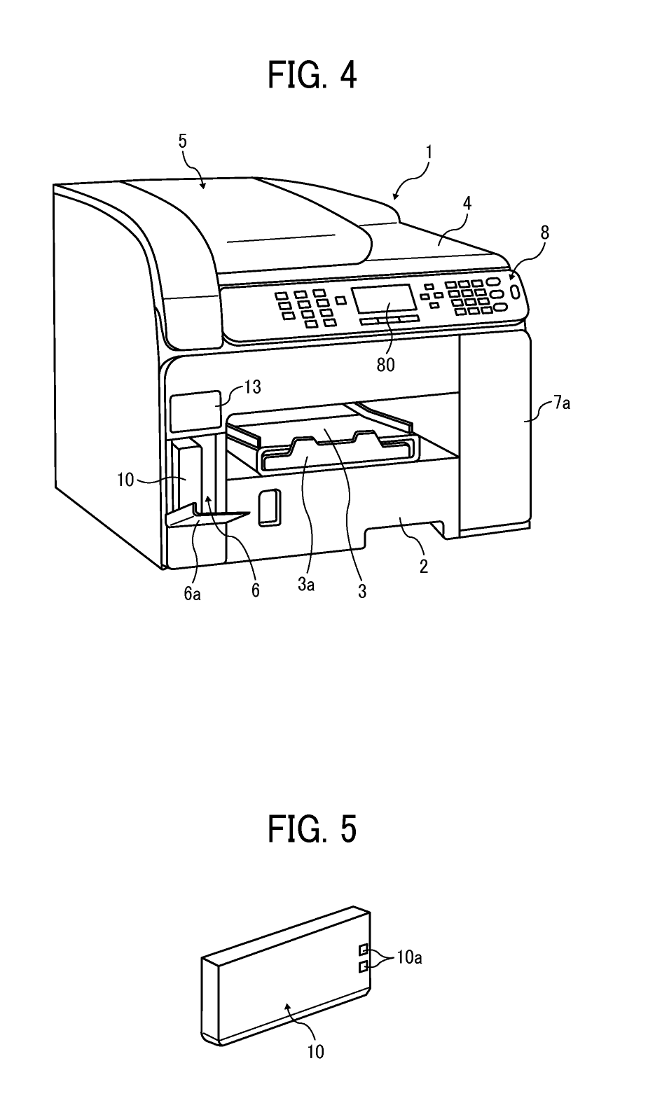

FIG. 4 is a perspective view of the example of the exterior of the inkjet printer, more specifically, a multi-functional inkjet printer (i.e., hereinafter referred to as MFP) including a battery. It is to be noted that the present invention is not specific to the MFP and may be also applied to a single function printer with only a printer function.

The MFP includes a printer main body 1 and a scanning unit 5. The MFP includes a copy function and a printer function, and may further include a facsimile function or a function to directly print from a digital camera or from a universal serial bus (hereinafter referred to as USB) memory.

The printer main body 1 includes the above-described mechanical structure of FIG. 1 and FIG. 2, and the control unit 100 described in FIG. 3.

The scanning unit 5 reads an image of a document set on a contact glass of the scanning unit 5, stores image data of the image, and transmits the image data to an external destination or forms a copy of the image data with the printer main body 1. The scanning unit 5 is included in the MFP so that transmitting the image data to the external destination and forming the copy of the image data with the printer main body 1 are possible.

External members of the printer main body 1 that can be seen from the outside include the upper cover 4; the operation panel 8, having a liquid crystal display 80, various keys, and switches, that is provided at a front side of the upper cover 4; and the above-described sheet feed tray 2 and sheet ejection tray 3 that can be operated from the front side. The sheet ejection tray 3 includes a sheet ejection stopper 3a that may be pulled out. The operation panel 8 may be made detachably attached, like a remote control unit, with respect to the printer main body 1.

At a right side of a front surface of the printer main body 1, a first cover 7a is provided. The first cover 7a may be opened, or closed to cover the above-described cartridge loading unit 7. At a left side of the front surface of the printer main body 1, a second cover 6a is provided. The second cover 6a may be opened or closed to cover a battery loading unit 6. A battery 10 that may be replaced is loaded in the battery loading unit 6.

An example of a battery pack serving as the battery 10 to drive the MFP is shown in FIG. 5. The MFP basically uses a dedicated battery pack. The battery 10 includes a pair of terminals 10a. When the battery 10 is loaded in the battery loading unit 6 of the printer main body 1, the terminals 10a are connected to corresponding terminals of the printer main body 1 and power of the battery 10 is supplied to the printer main body 1. A lithium ion battery or a nickel hydrogen battery may be used as the battery 10.

At the front surface of the printer main body 1 and above the battery loading unit 6, a battery state display panel 13 as shown in FIG. 6 is provided. The battery state display panel 13 displays a battery loaded indicator 131 indicating the battery 10 is loaded, a no battery indicator 132 indicating there is no battery 10, and a power level indicator 133 indicating a level of a remaining amount of power when the battery 10 is loaded. The power level indicator 133 is formed of five bar shaped light-emitting members (e.g., built-in light emitting diodes, hereinafter referred to as LED) that indicate the level of the remaining amount of power of the battery 10 in five levels. When the remaining amount of power of the battery 10 becomes a set value or less, a low power indicator 134 is displayed.

Each of the above-described indicators is displayed by lighting an LED and becomes visible to a user. It is to be noted that the battery state display panel 13 may also display each of the above-described indicators as patterns on a single liquid crystal display panel.

When the power of the MFP is OFF or the MFP is in an energy saving standby, each of the above-described indicators are set to not light up to reduce power consumption, and are set to light up when a first switch 135 is pressed. The printer main body 1 further includes an LED lighting to illuminate an upper portion of the sheet ejection tray 3. The battery state display panel 13 further includes a second switch 136 to turn ON or OFF the LED lighting.

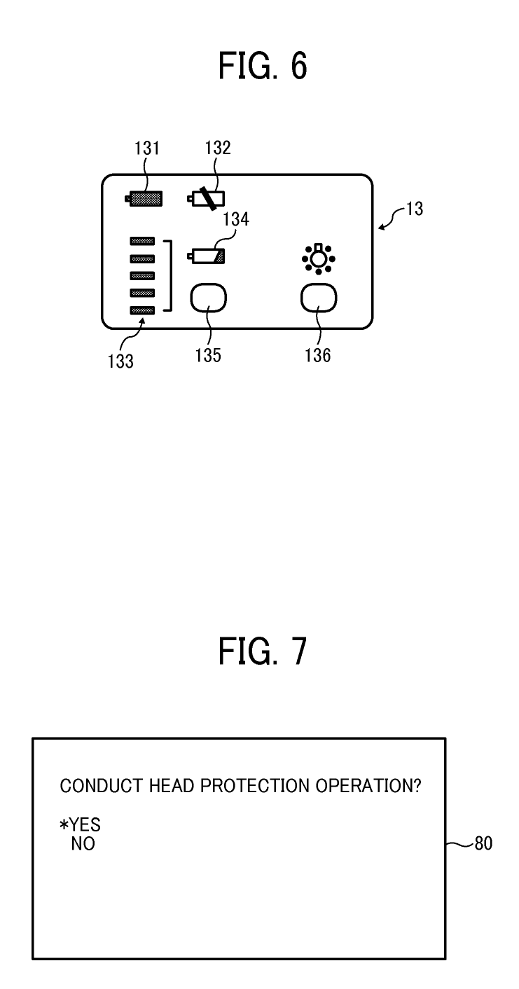

In FIG. 7, a text display example of the liquid crystal display 80 of the operation panel 8 is shown. The meaning of the text display example is described later.

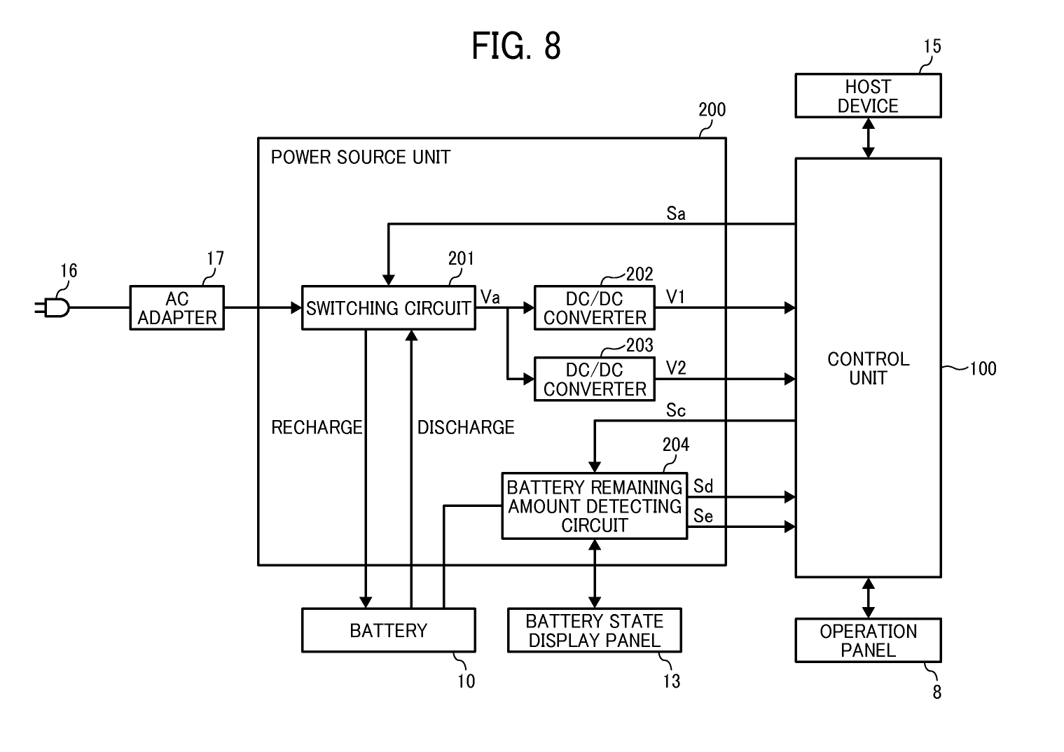

Next is a description of a power source unit 200 and action of related members in the MFP with reference to FIG. 8.

The power source unit 200 includes a switching circuit 201, a first DC/DC converter 202, a second DC/DC converter 203, and a battery remaining amount detecting circuit 204.

The power source unit 200 enables switching between power supplied from the battery 10 and power supplied from an AC adapter 17 to drive the MFP.

More specifically, a direct current discharge of the loaded battery 10 is sent to the switching circuit 201. An alternating current supplied, via a power source plug 16, from a commercial power source is converted to a direct current of a predetermined voltage with the AC adapter 17 and sent to the switching circuit 201.

The switching circuit 201 is formed of a field effect transistor (hereinafter referred to as FET) and a control integrated circuit (hereinafter referred to as IC). When the battery 10 is not loaded and the AC adapter 17 is connected, the switching circuit 201 outputs the direct current from the AC adapter 17 to the first DC/DC converter 202 and the second DC/DC converter 203.

When the battery 10 is loaded and the AC adapter 17 is not connected, the switching circuit 201 outputs the direct current from the battery 10 to the first DC/DC converter 202 and the second DC/DC converter 203. When the battery 10 is loaded and the AC adapter 17 is connected, the direct current from either the battery 10 or the AC adapter 17 is outputted to the first DC/DC converter 202 and the second DC/DC converter 203 according to a power source switching signal Sa from the control unit 100. Further, when the direct current from the AC adapter 17 is outputted, a portion of the direct current recharges the battery 10.

The first DC/DC converter 202 and the second DC/DC converter 203 convert a constant direct current voltage Va outputted from the switching circuit 201 into a first direct current voltage V1 and a second direct current voltage V2, respectively. The first direct current voltage V1 and the second direct current voltage V2 have different voltage values. Then, the first direct current voltage V1 and the second direct current voltage V2 are supplied to the control unit 100 shown in FIG. 3. The first direct current voltage V1 and the second direct current voltage V2 are voltages for driving the control unit 100, and driving the recording head 24, the main scanning motor 61, and the sub-scanning motor 62.

The battery remaining amount detecting circuit 204 is a battery remaining amount detecting unit to detect the remaining amount of stored power of the battery 10 with a comparator IC that compares an output voltage of the battery 10 with a reference voltage pre-set at a voltage dividing resistor.

According to the remaining amount of power detected by the battery remaining amount detecting circuit 204, the LEDs of the power level indicator 133, shown in FIG. 6, of the battery state display panel 13 are lighted indicating the remaining amount of power in five levels. More specifically, more power of the battery 10 remains when more LEDs of the power level indicator 133, from the LED provided at the bottom, are lighted.

When the battery 10 is loaded, the battery loaded indicator 131 is lighted. When the battery 10 is not loaded, the no battery indicator 132 is lighted. When the remaining amount of power of the battery 10 becomes the set value or less, the low power indicator 134 is displayed to warn that the remaining amount of power of the battery 10 is the set value or less, and prompts the user to connect the AC adapter 17. When the low power indicator 134 is displayed, a low power signal Sd is sent from the battery remaining amount detecting circuit 204 to the control unit 100. When the remaining amount of power of the battery 10 reaches the threshold value or less that is the point at which the image forming action (i.e., printing action) is stopped, a remaining power insufficient signal Se is sent from the battery remaining amount detecting circuit 204 to the control unit 100. The battery remaining amount detecting circuit 204 is controlled by a control signal Sc from the control unit 100.

The above-described threshold value of the remaining amount of power of the battery 10 is preferably a value that corresponds to sufficient remaining power for a head protection operation with a head protection unit such as the cap 47 of the maintaining/recovery unit 46 shown in FIG. 2.

In the control unit 100, the ASIC 107 shown in FIG. 3 detects a state of the remaining amount of power of the battery 10 from the low power signal Sd and the remaining power insufficient signal Se from the battery remaining amount detecting circuit 204, and the CPU 101 checks the state. In a case in which the low power signal Sd is detected and the AC adapter 17 is connected, the control unit 100 switches supplying of power to the AC adapter 17 with the power source switching signal Sa, and recharges the battery 10.

In a case in which the remaining power insufficient signal Se is detected by the ASIC 107 of the control unit 100 and when the CPU 101 checks the state, normally, the printing action is stopped, capping with the cap 47 shown in FIG. 2 to protect the recording head 24 is conducted, and a control of turning power OFF is promptly conducted.

Accordingly, the threshold value, at which the battery remaining amount detecting circuit 204 outputs the remaining power insufficient signal Se, is set at a point in which the battery 10 has a margin of power to conduct capping that is the head protection operation when the recording head 24 does not print.

There are cases in which the user would like to execute printing instead of capping to protect the recording head 24. In the image forming apparatus according to an embodiment of the present invention, when the user would like to execute printing instead of capping, the remaining power insufficient signal Se is ignored and printing is conducted until power of the battery 10 is completely used up. More specifically, the image forming apparatus continues to enforce printing as long as the printing action is possible.

A setting of whether or not to conduct the head protection operation, that is automatic capping, is possible by operating the keys of the operation panel 8 shown in FIG. 4. The setting can be confirmed with the text display example of the liquid crystal display 80 as shown in FIG. 7. In the text display example, the asterisk mark “*” indicates the setting. More specifically, the text display example “conduct head protection operation?” and “*NO” is a setting to execute enforced printing, and is stored, for example, in the RAM 103 serving as a storing unit of the control unit 100 shown in FIG. 3. Thus, the text display example “conduct head protection operation?” and the asterisk mark correspond to a setting of enforced printing of a setting unit (e.g., CPU 101).

It is to be noted that in a case in which the above-described setting of enforced printing is not set at the MFP, operation of setting can be made easier for the user if the above-described setting of enforced printing can be conducted at the host device 15, such as a personal computer, shown in FIG. 8 when transmitting a print job from the host device 15 to the MFP.

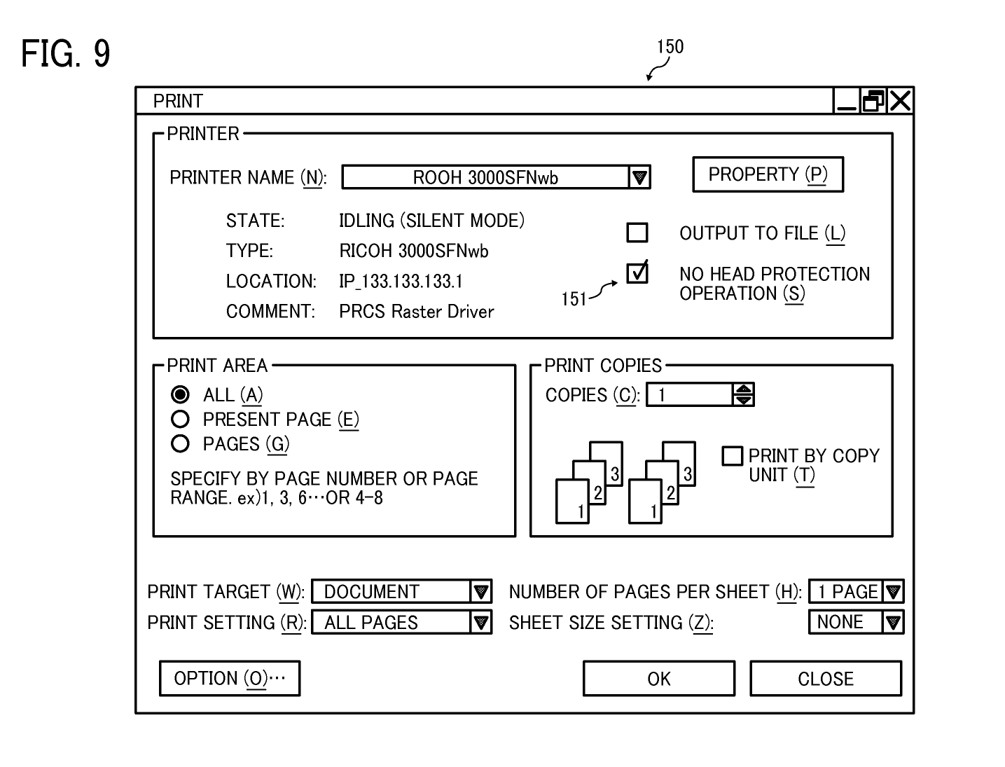

FIG. 9 is an example of a print setting screen 150 of the printer driver of the host device 15 that enables the setting of enforced printing. For example, as shown in FIG. 9, the print setting screen 150 includes a check box 151 of “No head protection operation”. When the user inputs a check in the check box 151 (i.e., sets enforced printing) and the printer driver transmits the print job with the checked check box 151, the host I/F 105 of the control unit 100 receives the print job, and the RAM 103 serving as the storing unit stores the setting of enforced printing.

Accordingly, the printer main body 1 of the MFP continuously prints until the power of the battery 10 is completely used up and continuation of the printing action is not possible.

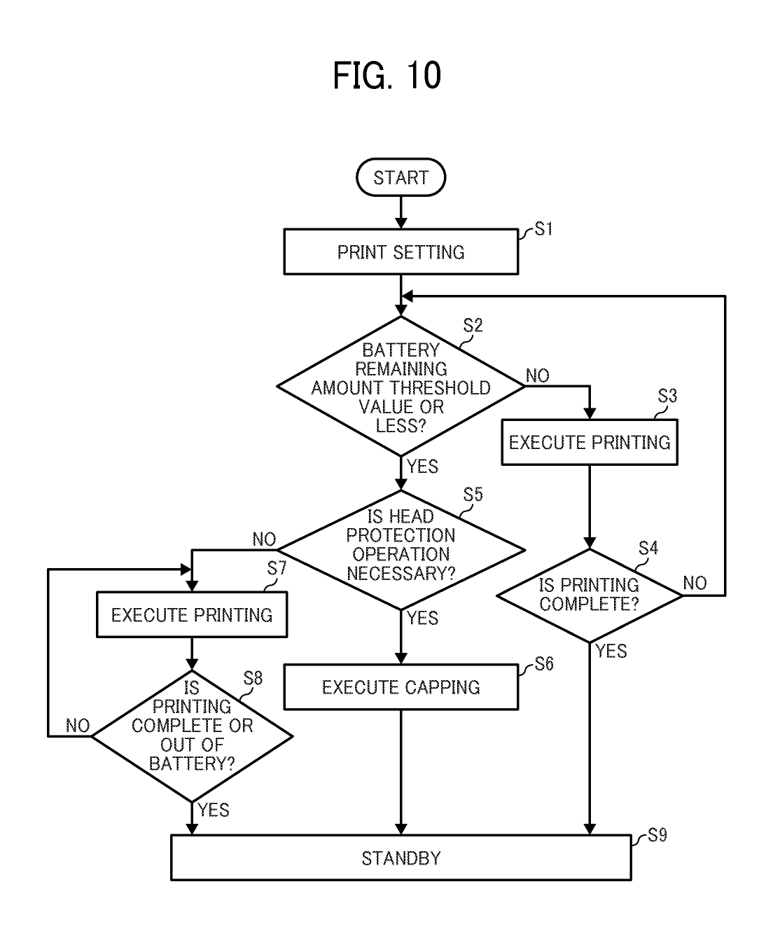

FIG. 10 is a flow chart showing an example of a process of a print control conducted by the CPU 101 of the control unit 100, shown in FIG. 3, of the printer main body 1.

When the print job is received from the host device 15 by the host I/F 105 shown in FIG. 3, the CPU 101 detects completion of the print setting and starts the process of FIG. 10.

In step S2, determination of whether the remaining amount of power of the battery 10 is at the threshold value or less is conducted. More specifically, when the remaining power insufficient signal Se is not inputted from the battery remaining amount detecting circuit 204 shown in FIG. 8 to the control unit 100, the remaining amount of power of the battery 10 is not at the threshold value or less, that is, greater than the threshold value (i.e., corresponding to NO). When the remaining power insufficient signal Se is inputted, the remaining amount of power of the battery 10 is at the threshold value or less (i.e., corresponding to YES).

When the remaining amount of power of the battery 10 is not at the threshold value or less, normal printing is conducted in step S3. In step 4, determination of whether or not printing is complete is conducted. If printing is not complete, the process returns to step S2 and if the remaining amount of power of the battery 10 is not at the threshold value or less, printing is continued. This is repeated until printing is determined to be complete in step S4. When printing is determined to be complete in step S4, the process proceeds to step 9 to switch the MFP to a state of standby.

When the remaining amount of power of the battery 10 is determined to be at the threshold value or less in step S2, whether or not to conduct the head protection operation is determined in step S5. More specifically, whether or not to conduct the head protection operation is determined by checking whether or not the setting of enforced printing, the above-described “conduct head protection operation?” corresponding to automatic capping and “*NO”, is stored in the RAM 103. When the setting of enforced printing is not stored in the RAM 103, a determination of conducting the head protection operation is made in step S5. After executing capping in step S6, the process proceeds to step 9 to switch the MFP to the state of standby.

When the setting of enforced printing is stored in the RAM 103, a determination of not conducting the head protection operation is made in step S5 and capping of step S6 is not executed. Then, in step 7, printing (i.e., enforced printing) is executed. This is enforced printing of an enforced printing unit (e.g., CPU 101). In step S8, determination of whether or not printing is complete, or whether or not power of the battery 10 is completely depleted is conducted. Printing executed in step 7 is continued until printing is determined to be complete or power is completely depleted in step S8. Then, the process proceeds to step 9 to switch the MFP to the state of standby. It is to be noted that the above-described “power of the battery 10 is completely depleted” is defined as a state in which the loaded battery 10 has discharged to a point of not being able to supply minimum power necessary for the printing action.

In a case in which printing, with the printer main body 1 set by the user, is continued until power of the battery 10 is completely depleted and printing finally stops in the middle of printing, it is more convenient to enable the printer main body 1 to transfer the print data to another printer shared on a network including the MFP and enable printing, as described below referring to a secondary exemplary embodiment.

The following is a description of the second exemplary embodiment of the present invention of the above-described case.

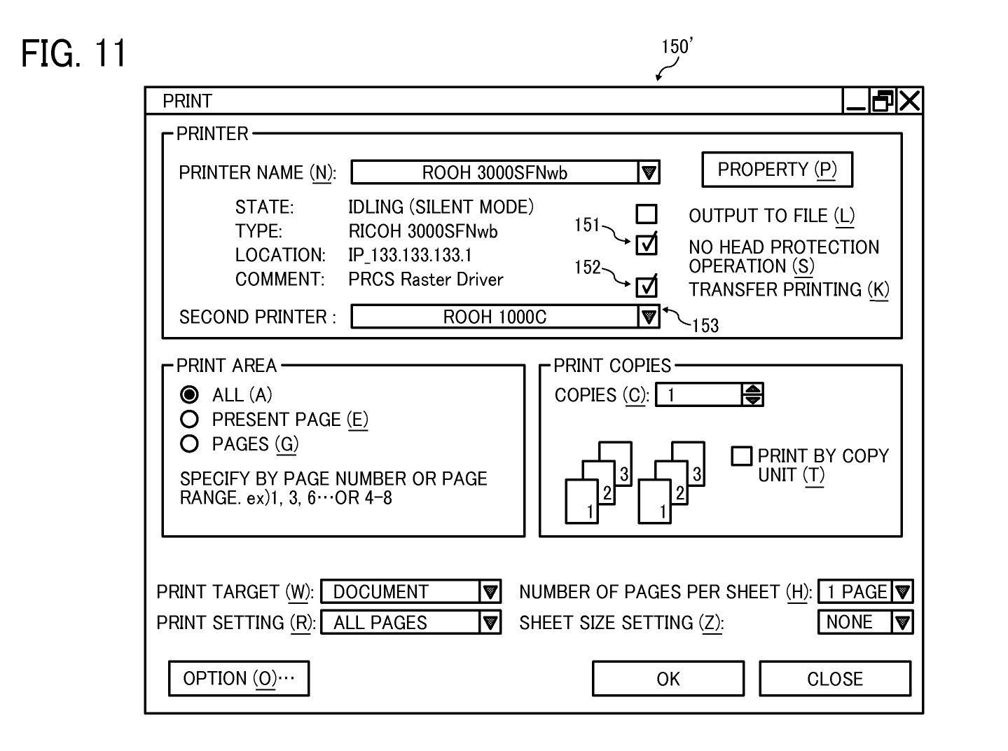

FIG. 11 is an example of a print setting screen 150′. More specifically, FIG. 11 is a modified example of the print setting screen 150 of the printer driver of the host device 15 in the second exemplary embodiment. For example, when the user inputs a check in a checkbox 151 of “no head protection operation”, inputs a check in a checkbox 152 of “transfer printing”, inputs or selects a printer name of another shared printer at a combo box 153 of a “second printer” to execute transfer printing, and clicks an “OK” button, the printer driver transfers a print job to a set main printer that is the MFP.

More specifically, information of a setting of enforced printing, a setting of transfer printing, and information of the second printer is included in the print job. When a host I/F 105 of a control unit 100 of a MFP receives the information of the above-described settings and the second printer, a RAM 103 serving as the storing unit stores the information of the above-described settings and the second printer.

The above-described information, stored in the RAM 103, corresponds to the setting of enforced printing, the setting of transfer printing, and identification of the second printer (i.e., external image forming apparatus) that executes transfer printing.

It is to be noted that the above-described settings and identification of the second printer can also be set with an operation panel 8 shown in FIG. 4.

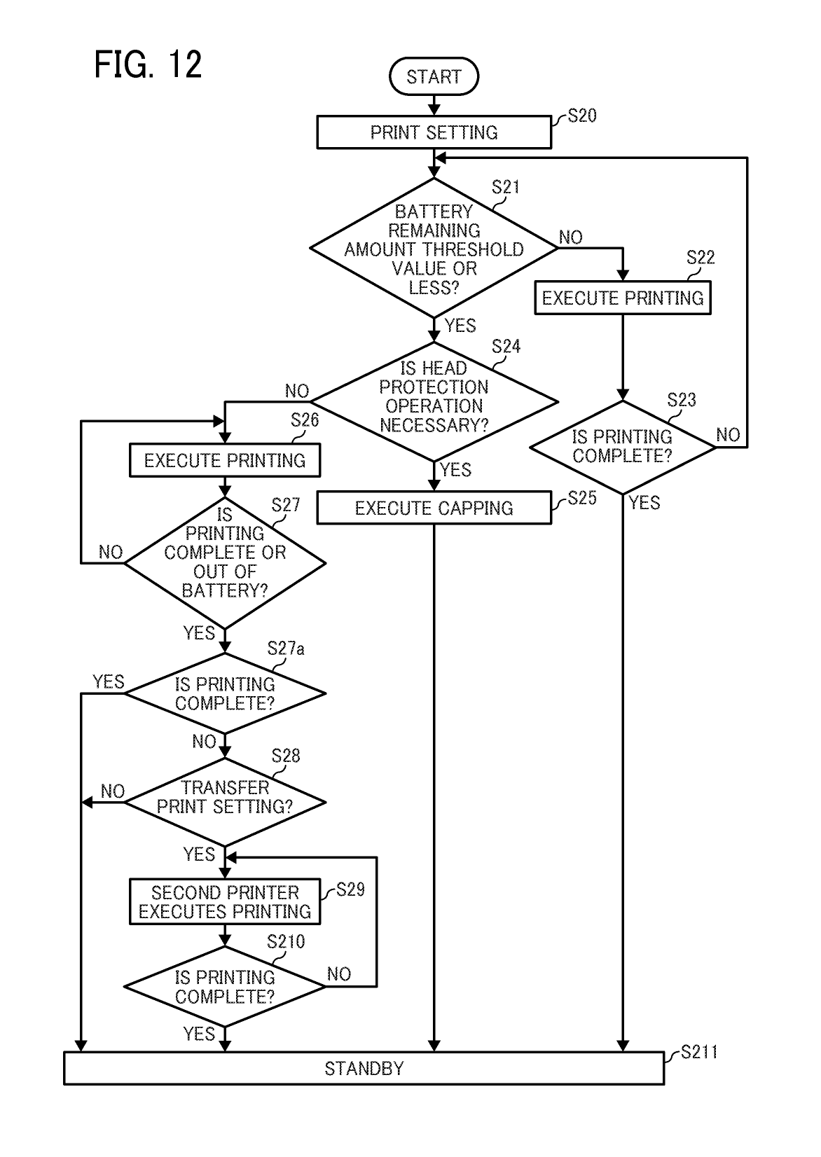

FIG. 12 is a flow chart showing an example of a process of a print control conducted by a CPU 101 of a control unit 100, as shown in FIG. 3, of a printer main body 1 of the above-described second exemplary embodiment.

It is to be noted that in the following description of the process of the print control of the above-described second exemplary embodiment, steps S21 to S27 are the same as steps S2 to S8 of the process of FIG. 10. Thus, redundant descriptions thereof are omitted.

In the above-described second exemplary embodiment, when printing is determined to be complete or when power of a battery 10 is determined to be completely depleted in step S27, determination of whether or not printing is complete is conducted in step S27a. When printing is complete, the process proceeds to a state of standby in step 211. When printing is not complete, the process proceeds to determine whether or not the above-described transfer printing is set by checking the RAM 103 with stored information in step S28.

When transfer printing is not set, the process proceeds to the state of standby in step 211. When transfer printing is set, the process proceeds to step S29, and transfers remaining data of the print job to the second printer that is shared on the network including the MFP and executes transfer printing with the second printer. This is transfer printing of a transfer unit (e.g., CPU 101).

The printer name of the second printer is stored in the RAM 103. Accordingly, printing is continued with the second printer until printing is determined to be complete in step S210. After printing is determined to be complete in step S210, the process proceeds to the state of standby in step 211.

Further, in the above-described printing with the second printer, wasteful printing may be prevented by transferring remaining data that is remaining-print data, of the print job, that corresponds to a page at which printing is terminated and pages thereafter.

More specifically, to prevent wasteful printing, a counter unit (e.g., CPU 101 of the control unit 100 as shown in FIG. 3) to count pages of the printing print job is included in the above-described second exemplary embodiment. The count is not increased (i.e., page increments) until printing moves on to the next page. Thus, when printing is terminated due to power of the battery 10 becoming completely depleted, the remaining-print data that corresponds to the page at which printing is terminated (i.e., more specifically, last page increment) and pages thereafter are transferred to the second printer serving as the shared image forming apparatus.

As described above, even if power of the battery 10 of the MFP serving as the main printer becomes completely depleted, printing of the print job of the user can be completed. In addition, no wasteful printing occurs.

A setting to automatically conduct layout printing to secure prints of the print job as much as possible when power of the battery 10 is low may also be included, as described below referring to a third exemplary embodiment.

The following is a description of the third exemplary embodiment of the present invention of the above-described case.

The setting of layout printing may be set, by the user, in a print setting screen 150 of a printer driver or an operation panel 8 of a printer main body 1 when setting enforced printing. Layout printing is defined as printing multiple pages of print data (i.e., image data) on a single sheet P. When layout printing is set, a RAM 103 serving as a storing unit of a control unit 100 of a MFP stores the setting.

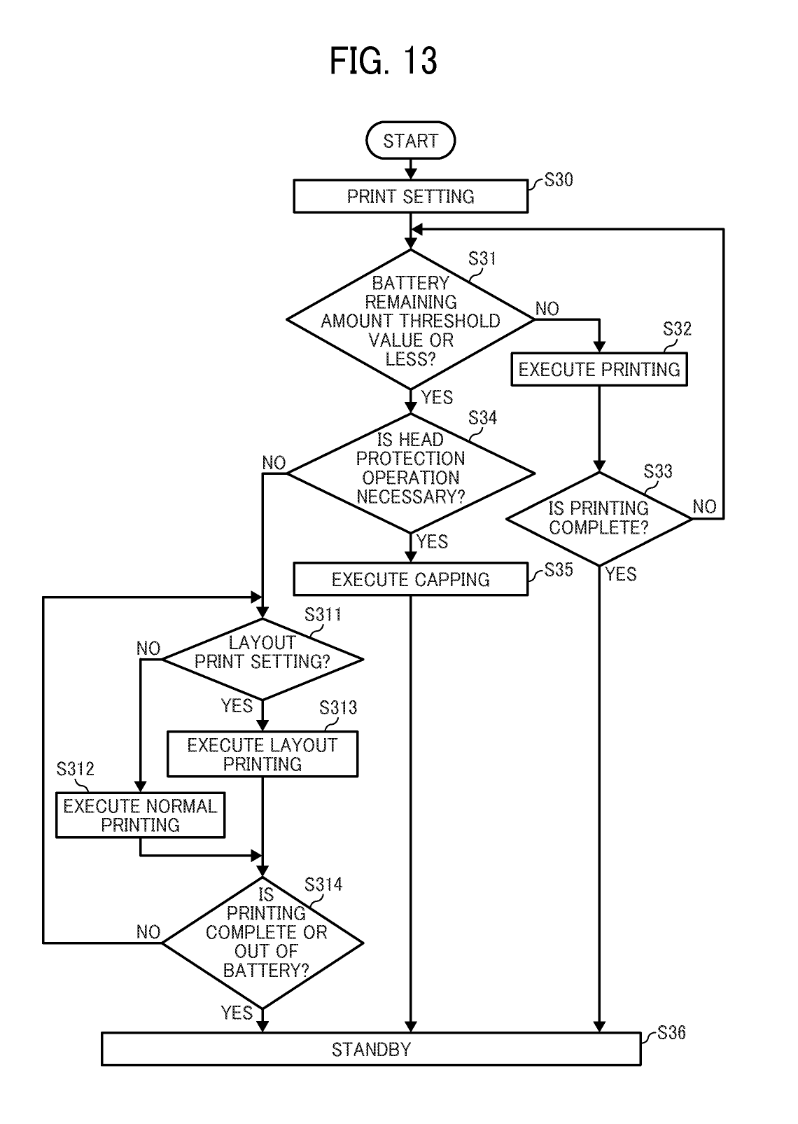

FIG. 13 is a flow chart showing an example of a process of a print control conducted by a CPU 101 of a control unit 100, as shown in FIG. 3, of a printer main body 1 of the third exemplary embodiment including the setting of layout printing.

It is to be noted that in the following description of the process of the print control that includes the setting of layout printing, steps S31 to S34 are the same as steps S2 to S5 of the process of FIG. 10. Thus, redundant descriptions thereof are omitted.

In a case in which a head protection operation is determined to not be conducted (i.e., enforced printing is set) in step S34, the process proceeds to determine whether or not layout printing is set in step S311. When layout printing is not set, printing is executed in step S312. Then, in step S314, determination of whether or not printing is complete and determination of whether or not power of the battery 10 is completely depleted are conducted. If printing is not complete, the process returns to step S311. This is repeated until printing is determined to be complete or power of the battery 10 is completely depleted in step S314. In the above-described case, printing is enforced printing. More specifically, the head protection operation is not conducted and a printing action is conducted.

When layout printing is determined to be set, layout printing is executed in step S313. Then, in step S314, determination of whether or not printing is complete and whether or not power of the battery 10 is completely depleted are conducted. If printing is not complete, the process returns to step S311. This is repeated until printing is determined to be complete or power of the battery 10 is completely depleted in step S314. This is layout printing of a layout printing unit (e.g., CPU 101) and is one example of the enforced printing unit. When printing is determined to be complete or power of the battery 10 is completely depleted in step S314, the process proceeds to a state of standby that is step S36.

The layout printing may also be made to be executed at all times when enforced printing is conducted by pre-setting layout printing in a firmware in a ROM 102 of the control unit 100 as shown in FIG. 3.

Accordingly, in a case in which enforced printing is executed when a remaining power of the battery 10 reaches a threshold value or less, by conducting layout printing of printing two pages of print data on a single sheet P, an output of printed pages that is twice an output of printed pages with normal printing is obtained. Thus, a possibility of completely printing a remaining number of pages is increased.

A layout printing of printing three pages or more of print data on a single sheet P is also possible. However, the more pages that are printed on the single sheet P, reduction ratio increases and reading becomes more difficult.

The present invention is not limited to the above-described inkjet printers, that are examples of an image forming apparatus according to an embodiment of the present invention, and may be applied to any type of image forming apparatus as long as the image forming apparatus is driven with power from a battery. Specific examples of types of the image forming apparatus driven with power from the battery include, but are not limited to, a thermal transfer type, a thermal sensitive type, and an electrophotographic type employing an LED array head.

Regarding the battery, a capacity attenuation curve of the battery, generally, differs according to an environment temperature or a service life of the battery. Thus, with respect to any type of the image forming apparatus, a threshold in which a printing action is stopped is set at a point with a certain margin to enable completion of an ending action irrelevant to the environment temperature or a length of the service life of the battery.

Further, in a case of the electrophotographic type image forming apparatus, there is a possibility of remaining toner on a photoconductor dispersing inside a body of the electrophotographic type image forming apparatus, fouling the inside of the body, and impairing the photoconductor when power is terminated. Thus, a threshold at which printing action is stopped is set at a point in which a battery has a certain margin of power, i.e. a certain margin of remaining power, to conduct an ending action cancelling of a job and an ending process.

The present invention enables enforced printing by using remaining power of the battery left after reaching the threshold.

Application of the present invention is not limited to a single function printer or a multi-function peripheral. The present invention also may be applied to copiers, facsimiles, and various recording devices.

The present invention is not limited to the above-described exemplary embodiments, but may be modified and improved within the scope of the present disclosure.

As described above, the image forming apparatus according to the embodiment of the present invention can enforce image forming (i.e., printing) even when the remaining amount of power of the battery reaches the predetermined threshold value or less.

What is claimed is:

1. An image forming apparatus driven with stored power from a battery, comprising:
an image forming unit to perform printing;
a battery remaining amount detecting unit to detect a remaining amount of the stored power of the battery; and
an enforced printing unit to determine whether the detected remaining amount of the stored power of the battery reaches a threshold value indicating to stop printing, and controls the image forming unit to continuously perform printing even when it is determined that the detected remaining amount reaches the threshold value.

2. The image forming apparatus of claim 1, further comprising:
a setting unit to receive an instruction to execute enforced printing,
wherein the enforced printing unit controls the image forming unit to continuously perform printing even when it is determined that the detected remaining amount reaches the threshold value, only when the setting unit receives the instruction to execute enforced printing.

3. The image forming apparatus of claim 1, further comprising:
a storing unit to store an instruction to execute enforced printing, received from a host apparatus that sends a print job,
wherein the enforced printing unit controls the image forming unit to continuously perform printing even when it is determined that the detected remaining amount reaches the threshold value, only when the storing unit stores the instruction to execute enforced printing.

4. The image forming apparatus of claim 1, further comprising:
a transfer unit to transfer, when a print job is not completed by the image forming unit, remaining data of the print job to an external image forming apparatus that is connected with the image forming apparatus via a network, and causes the external image forming apparatus to execute printing to complete the print job.

5. The image forming apparatus of claim 4, further comprising:
a counter unit to count pages of the print job that are printed by the image forming unit,
wherein when the print job is not completed by the image forming unit, the transfer unit transfers remaining pages of the print job that are not printed by the image forming unit, to the external image forming apparatus.

6. The image forming apparatus of claim 4, further comprising:
a storing unit to store an instruction for executing transfer printing with the external image forming apparatus and an identification of the external image forming apparatus, the instruction being received at an operation panel of the image forming apparatus or received from a network,
wherein the transfer unit transfers the remaining data of the print job to the external image forming apparatus, only when the instruction for executing and the identification of the external image forming apparatus are stored in the storing unit.

7. The image forming apparatus of claim 1, wherein the enforced printing unit includes a layout printing unit that performs layout printing to print multiple pages of image data on a single sheet.

8. The image forming apparatus of claim 7, further comprising:
a storing unit to store an instruction for executing layout printing, the instruction being received at an operation panel of the image forming apparatus or received from a network,
wherein the layout printing unit executes layout printing only when the instruction for executing layout printing is stored in the storing unit.

9. The image forming apparatus of claim 7, wherein the layout printing unit executes layout printing at all times when executing enforced printing.

10. The image forming apparatus of claim 1, wherein the image forming unit includes
a recording head to discharge ink droplets, and
a head protection unit to conduct a head protection operation to protect the recording head when printing is not conducted,
wherein the threshold value of the remaining amount of stored power of the battery is a value that is sufficient to perform the head protection operation with the head protection unit, and
wherein the enforced printing unit, when executing enforced printing, executes printing without conducting the head protection operation of the head protection unit.

11. An image forming method, performed by an image forming apparatus driven with stored power from a battery, the method comprising:
detecting a remaining amount of the stored power of the battery;
determining whether the detected remaining amount of the stored power of the battery reaches a threshold value indicating to stop printing; and
controlling an image forming unit to continuously perform printing even when it is determined that the detected remaining amount reaches the threshold value.

12. A non-transitory recording medium storing a plurality of instructions which, when executed by a processor, cause the processor to perform an image forming method, performed by an image forming apparatus driven with stored power from a battery, the method comprising:
detecting a remaining amount of the stored power of the battery;
determining whether the detected remaining amount of the stored power of the battery reaches a threshold value indicating to stop printing; and
controlling an image forming unit to continuously perform printing even when it is determined that the detected remaining amount reaches the threshold value.
